(19) United States
(12) Patent Application Publication
(10) Pub. No.: US 2012/0180858 A1
(43) Pub. Date: Jul. 19, 2012

(54) METHOD FOR MAKING SEMICONDUCTING FILM AND PHOTOVOLTAIC DEVICE

(75) Inventors: Dalong Zhong, Niskayuna, NY (US); Gautam Parthasarathy, Niskayuna, NY (US); Richard Arthur Nardi, JR., Scotia, NY (US)

(73) Assignee: GENERAL ELECTRIC COMPANY, SCHENECTADY, NY (US)

(21) Appl. No.: 13/005,602

(22) Filed: Jan. 13, 2011

(51) Int. Cl. H01L 31/0224; H01L 31/18; C23C 14/34; H01L 31/0296

(52) U.S. Cl. 136/256; 438/84; 438/98; 204/192.15; 257/E31.015; 257/E31.126

(57) ABSTRACT

One aspect of the present invention provides a method to make a film. The method includes providing a target comprising a sulfide within an oxygen free environment; applying a plurality of direct current pulses to the target to create a pulsed direct current plasma; sputtering the sulfide target with the pulsed DC plasma to eject a material comprising sulfur into the plasma; and depositing a film comprising the ejected material onto a support. Another aspect of the present invention provides a method of making a photovoltaic device.

### BACKGROUND

The invention relates generally to methods of making a semiconducting film used in an optoelectronic device by pulsed direct current magnetron sputtering. In particular, the invention relates to a method of making a cadmium sulfide film by pulsed direct current magnetron sputtering and photovoltaic devices made therefrom.

One of the main focuses in the field of photovoltaic devices is the improvement of energy conversion efficiency (from electromagnetic energy to electric energy or vice versa). Solar energy is abundant in many parts of the world year around. Unfortunately, the available solar energy is not generally used efficiently to produce electricity. Photovoltaic (“PV”) devices convert light directly into electricity. Photovoltaic devices are used in numerous applications, from small energy conversion devices for calculators and watches to large energy conversion devices for households, utilities, and satellites.

The cost of conventional photovoltaic cells or solar cell, and electricity generated by these cells, is generally comparatively high. For example, a typical solar cell achieves a conversion efficiency of less than 20 percent. Moreover, solar cells typically include multiple layers formed on a substrate, and thus solar cell manufacturing typically requires a significant number of processing steps. As a result, the high number of processing steps, layers, interfaces, and complexity increase the amount of time and money required to manufacture these solar cells.

Photovoltaic devices often suffer reduced performance due to loss of light, through, for example, reflection and absorption. Therefore, research in optical designs of these devices includes light collection and trapping, spectrally matched absorption and up/down light energy conversion. One of the ways to minimize the loss in a photovoltaic cell is to incorporate a window layer. It is well known in the art that the design and engineering of window layers should have as high a bandgap as possible to minimize absorption losses. Further, in order to enhance performance of the solar cell, it is desirable to make window layers that have good electrical and optical properties as well as thermal and chemical stability. The window layer should also be materially compatible with the absorber layer so that the interface between the absorber layer and the window layer contains negligible interface defect states. Typically, cadmium sulfide (CdS) has been used to make the window layer in photovoltaic cells, e.g. cadmium telluride (CdTe) and copper indium gallium diselenide (CIGS) solar cells. One major drawback for cadmium sulfide is its relatively low bandgap, which results in current loss in the device. A thin layer of cadmium sulfide is employed in photovoltaic devices to help reduce optical loss by absorption. However, issues such as shunts between the absorber layer and the transparent conductive oxide (TCO) exist in the photovoltaic devices due to the presence of the thin cadmium sulfide layer. To overcome the above disadvantages, it may be desirable to make the thin cadmium sulfide layer denser and better crystallized. In addition, the processing conditions to make some photovoltaic devices, for example devices that include cadmium telluride are harsh, and the layers are exposed to high temperatures, therefore thermal stability of the layers at the high temperatures is an important criterion.

Cadmium sulfide films are typically grown by radio frequency (RF) magnetron sputtering or chemical bath deposition. Using these methods, the cadmium sulfide thin film is typically grown into a cauliflower type of morphology having poor crystallinity. Further, the deposited cadmium sulfide film may not have the desired electrical and optical properties and may require subsequent treatment steps. RF sputtering of cadmium sulfide films on a large scale may further pose challenges, such as, for example, the spatial control of a uniform RF plasma may be difficult to achieve over large areas, scaling RF power for magnetron cathodes larger than a meter may be expensive, and the magnetron cathode for RF sputtering may have to be specially designed.

Therefore, there remains a need for an improved solution to the long-standing problem of inefficient and complicated solar energy conversion devices and methods of manufacture. Further, there is a need for improved methods for making cadmium sulfide layer having the desired crystallinity and morphology, and photovoltaic devices manufactured therefrom.

### BRIEF DESCRIPTION

In one aspect, a method is provided. The method includes providing a target comprising a semiconducting sulfide within an oxygen free environment; applying a plurality of direct current pulses to the target to create a pulsed direct current plasma; sputtering the target with the pulsed direct current plasma to eject a material comprising sulfur into the plasma; and depositing a film comprising the ejected material onto a support.

In another aspect, a method of making a photovoltaic device is provided. The method includes disposing a transparent window layer on a support; and disposing a semiconducting layer on the transparent window layer, wherein disposing the transparent window layer comprises providing a target comprising a semiconducting sulfide within an oxygen free environment; applying a plurality of direct current pulses to the target to create a pulsed direct current plasma; sputtering the target with the pulsed direct current plasma to eject a material comprising sulfur into the plasma; and depositing a film comprising the ejected material onto the support.

In yet another aspect, a method of making a photovoltaic device is provided. The method includes disposing a transparent conductive layer on a support; disposing a transparent window layer on the transparent conductive layer; and disposing a first semiconducting layer on the transparent window layer; wherein disposing the transparent window layer comprises providing a target comprising a semiconducting material comprising cadmium and sulfur within an oxygen free environment; applying a plurality of direct current pulses to the target to create a pulsed direct current plasma; sputtering the target with the pulsed direct current plasma to eject a material comprising cadmium and sulfur into the plasma; and depositing a film comprising the ejected material onto the transparent conductive oxide layer

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 illustrates a flow diagram of the method to make a film in accordance with an embodiment of the invention.

FIG. 2 illustrates a schematic of a photovoltaic device in accordance with an embodiment of the invention.

FIG. 3 illustrates a schematic of a photovoltaic device in accordance with another embodiment of the invention.

FIG. 4 illustrates the X-ray diffraction of a film in accordance with an embodiment of the invention.

### DETAILED DESCRIPTION

As described in detail below a method for depositing sulfide films using pulsed direct current (DC) magnetron sputtering is provided. Compared to conventional RF or DC magnetron sputtering, pulsed sputtering advantageously provides for deposition of sulfide film with controlled phase composition and tailorable film microstructure. Further, using pulsed direct current sputtering, sulfide films with low defect density can be achieved even at reduced support temperatures. In some embodiments, the sulfide thin films deposited by pulsed magnetron sputtering method have improved crystallinity, optical and electrical properties compared to sulfide films deposited by RF magnetron sputtering.

While only certain features of the invention have been illustrated and described herein, many modifications and changes will occur to those skilled in the art. It is, therefore, to be understood that the appended claims are intended to cover all such modifications and changes as fall within the true spirit of the invention. In the specification and claims, reference will be made to a number of terms, which have the following meanings.

The singular forms “a”, “an” and “the” include plural referents unless the context clearly dictates otherwise. Approximating language, as used herein throughout the specification and claims, may be applied to modify any quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Similarly, “free” may be used in combination with a term, and may include an insubstantial number, or trace amounts, while still being considered free of the modified term.

As used herein, the terms “may” and “may be” indicate a possibility of an occurrence within a set of circumstances; a possession of a specified property, characteristic or function; and/or may qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances, an event or capacity can be expected, while in other circumstances, the event or capacity cannot occur—this distinction is captured by the terms “may” and “may be”.

“Optional” or “optionally” means that the subsequently described event or circumstance may or may not occur, and that the description includes instances where the event occurs and instances where it does not. The terms “comprising”, “including”, and having are intended to be inclusive and mean that there may be additional elements other than the listed elements. Furthermore, whenever a particular feature of the invention is said to consist of at least one of a number of elements of a group and combinations thereof, it is understood that the feature may comprise or consist of any of the elements of the group, either individually or in combination with any of the other elements of that group.

It is also understood that terms such as “top,” “bottom,” “outward,” “inward,” and the like are words of convenience and are not to be construed as limiting terms. As used herein, the terms “disposed over”, or “disposed between” refers to both secured or disposed directly in contact with and indirectly by having intervening layers therebetween.

As previously noted, one embodiment of the present invention is a method for making a film. The method includes providing a target comprising a semiconducting sulfide within an oxygen-free environment; applying a plurality of direct current (DC) pulses to the target to create a pulsed direct current (DC) plasma; sputtering the target with the pulsed direct current plasma to eject a material comprising sulfur into the plasma; and depositing a film comprising the ejected material onto a support.

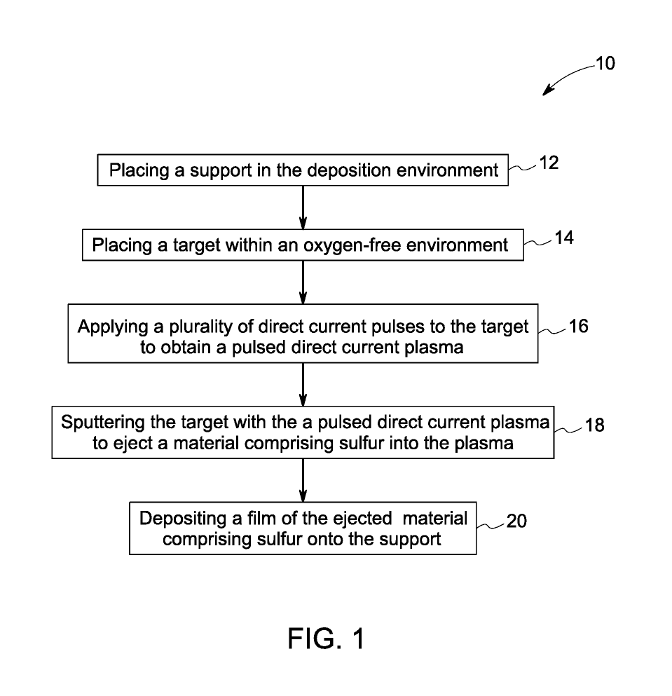

FIG. 1 represents a flow diagram 10 of a method to make a film according to one embodiment of the present invention. Step 12 provides a support in a deposition environment, for example, a deposition chamber. In one embodiment the support may include a glass, a polymer, a metal, or a composite. In another embodiment, the support may further include a layer of a transparent conductive material deposited on the support. In yet another embodiment, the support may include multiple layers disposed on the surface such as, for example, a reflective layer, a transparent conductive layer, and a high resistive transparent layer (buffer). In such embodiments, the window layer is deposited on the transparent conductive layer or the buffer layer (if present). In an alternative embodiment, the support includes a back contact layer disposed on the support and a first semiconducting layer disposed on the back contact layer. In such embodiments, the window layer is deposited on the first semiconducting layer. The support may be oriented and fixed within the deposition environment by methods known to one skilled in the art, for example the support may be fixed by means of a holder.

In step 14, a target is provided within an oxygen-free environment. As used herein the term “oxygen-free” refers to an environment without intentional addition of oxygen, wherein the amount of oxygen is less than about 0.05 weight percent. The target includes the sulfide material that is to be deposited on the support. In one embodiment, the target includes a semiconductor material comprising a sulfide. In another embodiment, the target includes a semiconductor material that includes compounds containing cadmium and sulfur. In one embodiment, the target may also include zinc. In another embodiment, the target may further include zinc oxide. In yet another embodiment, the target includes an alloy of zinc cadmium sulfide represented by the formula ZnₓCd₁₋ₓS, where x is a number in a range from about 0 to about 0.99. In a particular embodiment, the target includes cadmium sulfide. In one embodiment, the target may be placed at a predetermined distance from the support.

As noted earlier, direct current sputtering or pulsed direct current (DC) sputtering is typically used with metal targets such as cadmium or cadmium zinc alloy to make cadmium sulfide or cadmium zinc sulfide films. The use of metal targets to make sulfide thin film from metal targets typically requires a vapor source containing sulfur in the sputtering atmosphere, which creates manufacturing challenges such as process instability and target poisoning. Thus, use of pulsed DC sputtering of semiconducting targets may avoid some of the problems associated with depositing sulfide films.

In one embodiment, the target may be placed in an inert gas environment. Non-limiting examples of inert gas that may be used include argon, helium, nitrogen, and combinations thereof. In one embodiment, the inert gas employed is argon. Typically, the partial pressure of the inert gas inside the deposition environment is maintained in a range from about 0.1 Pascals to about 3 Pascals.

Step 16 involves applying a plurality of direct current pulses to the target to obtain a pulsed direct current plasma. Examples of direct current pulses that may be applied to the target include a bipolar asymmetric pulsed direct current power, pulsing at a frequency of tens to hundreds of kiloHertz (kHz). Typically one skilled in the art would appreciate that when the direct current pulses are applied to the target in an environment of an inert gas, ionization of the gases may also occur. In step 18, the target is sputtered with the pulsed direct current plasma to eject a material that includes sulfur into the plasma, via a pulsed sputtering process. As used herein the term “pulsed sputtering” is a physical vapor deposition method employing ion sputtering or magnetron sputtering of the target to produce a coating or a film on a surface.

In one embodiment, the sputtering is carried out at a pressure in a range from about 0.1 Pascals to about 3 Pascals at an average power of about 500 Watts to about 2000 Watts, depending on the size of the target. In one embodiment, direct current pulses have a power density in a range from about 0.2 W/cm² to about 20 W/cm². In another embodiment, the average power density is in a range from about 0.2 W/cm² to about 2 W/cm². In one embodiment, the direct current pulses have a current density (relative to target size) in a range from about 0.001 A/cm² to about 0.01 A/cm². In yet another embodiment, the direct current pulses have a pulse width (also referred as “reverse time”) in a range from about 0.2 microseconds to about 50 microseconds. In certain embodiments, direct current pulses have a pulse width in a range from about 1 microseconds to about 5 microseconds. In one embodiment, the direct current pulses results in a modulated pulse plasma in a frequency range from about 10 kHz to about 400 kHz.

Without being bound theory it is believed that pulsed direct current sputtering facilitates production of a highly ionized flux of target material to be deposited on the support, thereby facilitating the deposition of improved thin-film layers with high material utilization, high deposition rate, and good crystallinity while maintaining low support temperatures. In one embodiment, the sputtering is carried out at a support temperature in a range from about 20 degrees Celsius to about 550 degrees Celsius, and in some embodiments at a support temperature in a range from about 100 degrees Celsius to about 300 degrees Celsius. In another embodiment, the sputtering is carried out at ambient temperature, that is, the support is not heated.

The method further provides a step 20 for depositing a film of the ejected material onto the support. The film deposited on the support includes sulfur. In one embodiment, the film further includes cadmium, zinc, or combinations thereof. In some embodiments, the film includes ZnₓCd₁₋ₓS, wherein “x” is in a range from 0 to about 1. In one embodiment, “x” is in a range from about 0.1 to about 0.9, from about 0.2 to about 0.8, or from about 0.3 to about 0.6. In a particular embodiment, the film includes cadmium sulfide.

In one embodiment, the thickness of the film deposited is at least about 10 nanometers. In another embodiment, the thickness of the film is in a range from about 20 nanometers to about 200 nanometers. The deposition of the film may be controlled by controlling a number of parameters, for example pressure, temperature, the energy source used, sputtering power, pulsing parameters, the size and characteristics of the target material, the distance or space between the target and the support, as well as the orientation and location of the target material within the deposition environment. Selection of the sputtering power may depend in part on the support size and the desired deposition rate.

In one embodiment, the method further includes a step of annealing the film. The annealing of the film may be carried out for a duration from about 1 minute to about 30 minutes. The annealing may be carried out at a temperature in a range from about 100 degrees Celsius to about 550 degrees Celsius. In yet another embodiment, the annealing is carried out at a temperature of about 200 degrees Celsius.

In one embodiment, the film has an electrical resistivity in a range from about 0.1 Ohm-centimeter (Ω-cm), to about 1000 Ohm-centimeter. In some embodiments, the film has an electrical resistivity in a range from about 0.1 Ohm-centimeter to about 100 Ohm-centimeter. The electrical resistivity values may be for the as-deposited film or for the annealed film. In some embodiments, the method of the present invention advantageously provide for deposition of cadmium sulfide film having an electrical resistivity in a range from about 0.1 Ohm-centimeter to about 100 Ohm-centimeter

Without being bound by theory, it is believed that as the plasma is highly ionized, growing microcrystalline films, controlling their phase composition, and modifying the film microstructure may be accomplished at reduced support temperature using asymmetric pulsed direct current pulsed sputtering. In one embodiment, the as-deposited sulfide films are highly dense, smooth and conformal. As used herein, the term “as-deposited layers” refers to layers that are not post-treated (such as by annealing). In certain embodiments, the as-deposited films are substantially polycrystalline, and the grain size is equal to or greater than that of the same film deposited by conventional RF or DC sputtering at higher support temperature, while substantially decreasing the amount of defects, such as voids or pin-holes in the as-deposited films. In one embodiment, the film deposited by the present method has a microcrystalline morphology having a grain size in a range from about 50 nm to about 100 nm. In other embodiment, the grain size of the film deposited is in a range from about 100 nm to about 1000 nm, depending on the layer thickness. In one embodiment, the film deposited by the present method has a microcrystalline morphology. In some embodiments, the as-deposited sulfide film has a crystalline structure that is stable at the annealing conditions used for annealing the cadmium sulfide films, such as, for example, heating at 500 degrees Celsius for 10 minutes.

In certain embodiments, the film has a transmission of at least about 50 percent of the light in a wavelength in a range of about 300 nanometers to about 900 nanometer. In another embodiment, the film has a transmission of greater than about 80 percent of the light in a wavelength in a range of about 300 nanometers to about 900 nanometer.

In another aspect, a method of making a photovoltaic device is provided. The method includes disposing a transparent window layer on a support; and disposing a first semiconducting layer on the transparent window layer. The method of disposing the transparent window layer includes providing a target comprising a semiconducting sulfide within an oxygen free environment; applying a plurality of direct current pulses to the target to create a pulsed direct current plasma; sputtering the target with the pulsed direct current plasma to eject a material comprising sulfur into the plasma; and depositing a film comprising the ejected material onto the support. In some embodiments, the method further includes interposing a transparent conductive layer between the support and the transparent window layer. In some other embodiments, the method further includes interposing a buffer layer between the transparent window layer and the transparent conductive layer.

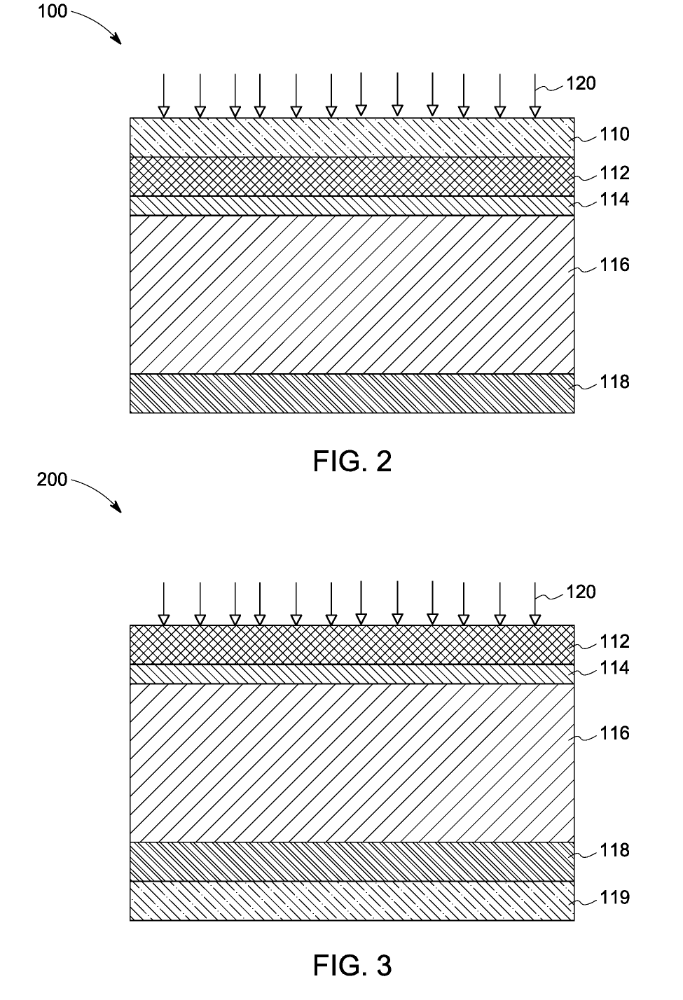

As illustrated in FIG. 2, in one embodiment, a photovoltaic device 100 is provided. The device 100 includes a layer, such as one or more layers 110, 112, 114, 116, and 118. In one embodiment, the photovoltaic device 100 includes a support 110 and a transparent conductive layer 112 disposed on the support 110. In the illustrated embodiment, a transparent window layer 114 is disposed on the transparent conductive layer 112. In one embodiment, a first semiconducting layer 116 is disposed on the transparent window layer 114. In some embodiments, a back contact layer 118 is further disposed on the first semiconducting layer 116.

The configuration of the layers illustrated in FIG. 2 may be referred to as a “superstrate” configuration because the light 120 enters from the support 110 and then passes on into the device. The support 110 is generally sufficiently transparent for visible light to pass through the support 110 and thus interact with the front contact layer 112. Suitable examples of materials used for the support 110 in the illustrated configuration include glass or a polymer. In one embodiment, the polymer comprises a transparent polycarbonate or a polyimide.

The transparent conductive layer and the back contact layers, during operation, carry electric current out to an external load and back into the device, thus completing an electric circuit. Suitable materials for transparent conductive layer 112 may include an oxide, sulfide, phosphide, telluride, or combinations thereof. These transparent conductive materials may be doped or undoped. In one embodiment, the transparent conductive layer 112 includes a transparent conductive oxide, examples of which include zinc oxide, tin oxide, cadmium tin oxide (Cd₂SnO₄), zinc tin oxide (ZnSnOₓ), indium tin oxide (ITO), aluminum-doped zinc oxide (ZnO:Al), zinc oxide (ZnO), fluorine-doped tin oxide (SnO:F), titanium dioxide, silicon oxide, gallium indium tin oxide(Ga—In—Sn—O), zinc indium tin oxide (Zn—In—Sn—O), gallium indium oxide (Ga—In—O), zinc indium oxide (Zn—In—O),and combinations of these. Suitable sulfides may include cadmium sulfide, indium sulfide and the like. Suitable phosphides may include indium phosphide, gallium phosphide, and the like.

Typically, when light falls on the solar cell 100, electrons in the first semiconducting layer (also sometimes referred to as “semiconductor absorber layer” or “absorber layer”) 116 are excited from a lower energy “ground state”, in which they are bound to specific atoms in the solid, to a higher “excited state,” in which they can move through the solid. Since most of the energy in sunlight and artificial light is in the visible range of electromagnetic radiation, a solar cell absorber should be efficient in absorbing radiation at those wavelengths. In one embodiment, the first semiconducting layer 116 includes a telluride, a selenide, a sulfide, or combinations thereof. In certain embodiments, the first semiconducting layer 116 comprises cadmium telluride, cadmium zinc telluride, cadmium sulfur telluride, cadmium manganese telluride, or cadmium magnesium telluride. Cadmium telluride (also sometimes referred to herein as “CdTe”) thin film typically has a polycrystalline morphology. Additionally, cadmium telluride is found to have a high absorptivity and a bandgap in a range from about 1.45 electron volts to about 1.5 electron volts. In one embodiment, the electronic and optical properties of cadmium telluride may be varied by forming an alloy of cadmium telluride with other elements or compounds for example, zinc, magnesium, manganese, and the like. Films of CdTe can be manufactured using low-cost techniques. In one embodiment, the CdTe first semiconducting layer 116 may comprise p-type grains and n-type grain boundaries.

In one embodiment, the transparent window layer 114 comprises the sulfide layer described previously, above. The transparent window layer 114, disposed on transparent conductive layer 116, is the junction-forming layer for device 100. The “free” electrons in the first semiconducting layer 116 are in random motion, and so generally there can be no oriented direct current. The addition of the transparent window layer 114, however, induces a built-in electric field that produces the photovoltaic effect. In one embodiment, the transparent window layer 114 includes cadmium sulfide. In one embodiment, the transparent window layer 114 may further include zinc telluride, zinc selenide, cadmium selenide, cadmium sulfur oxide, and or copper oxide. In one embodiment, the atomic percent of cadmium in the cadmium sulfide, in some embodiments, is in range from about 48 atomic percent to about 52 atomic percent. In another embodiment, the atomic percent of sulfur in the cadmium sulfide is in a range from about 45 atomic percent to about 55 atomic percent. In one embodiment, the transparent window layer 114 has a thickness in a range from about 5 nanometers to about 250 nanometers, or in a range from about 20 nanometers to about 200 nanometers. Typically, the first semiconducting layer 116 and the transparent window layer 114 provide a heterojunction interface between the two layers. In some embodiments, the transparent window layer 114 acts as an n-type window layer that forms the pn-junction with the p-type first semiconducting layer.

Typically, the back contact layer 118 transfers current into or out of device 100 depending on the overall system configuration. Generally, back contact layer 118 includes a metal, a semiconductor, graphite, or other appropriately electrically conductive material. In one embodiment, the back contact layer 118 includes a semiconductor comprising p-type grains and p-type grain boundaries. The p-type grain boundaries may assist in transporting the charge carriers between the back contact metal and the p-type semi-conductor layer. In some embodiments, the back contact layer may include one or more of a semiconductor selected from zinc telluride (ZnTe), mercury telluride (HgTe), cadmium mercury telluride (CdHgTe), arsenic telluride (As₂Te₃), antimony telluride (Sb₂Te₃), and copper telluride (CuₓTe).

In some embodiments, a metal layer (not shown) may be disposed on the back contact layer 118 for improving the electrical contact. In some embodiments, the metal layer includes one or more of group IB metal, or a group IIIA metal, or a combination thereof. Suitable non-limiting examples of group IB metals include copper (Cu), silver (Ag), and gold (Au). Suitable non-limiting examples of group IIIA metals (e.g., the low melting metals) include indium (In), gallium (Ga), and aluminum (Al). Other examples of potentially suitable metals include molybdenum and nickel.

In some other embodiments, the photovoltaic device may further include a buffer layer (not shown). In one embodiment, the buffer layer may be disposed on the transparent conductive layer. In another embodiment, the buffer layer may be disposed between the transparent conductive layer 112 and the transparent window layer 114. The buffer layer may be selected from tin oxide, zinc oxide, zinc tin oxide (Zn—Sn—O), or zinc indium tin oxide (Zn—In—Sn—O). In one embodiment, the device does not include a buffer layer.

In an alternative embodiment as illustrated in FIG. 3, a “substrate” configuration includes a photovoltaic device 200 wherein a back contact layer 118 is disposed on a support 119. Further a first semiconducting layer 116 is disposed on the back contact layer 118. A transparent window layer 114, comprising the sulfide layer described previously, is then disposed on the first semiconducting layer 116 and a transparent conductive layer 112 is disposed on the transparent window layer 114. In the substrate configuration, the support may include glass, polymer, or a metal foil. In one embodiment, metals that may be employed to form the metal foil include stainless steel, molybdenum, titanium, and aluminum. In one embodiment, the composition of the layers illustrated in FIG. 3, i.e. substrate 119, the transparent conductive layer 112, the transparent window layer 114, first semiconducting layer 116, and back contact layer 118, have the same compositions as described above in FIG. 2 having the superstrate configuration. In one embodiment, the first semiconducting layer 116 may be selected from copper indium disulfide (CIS), copper indium diselenide (CIS), copper indium gallium diselenide (CIGS), copper indium gallium sulfur selenium (CIGSS), copper indium gallium aluminum sulfur selenium (Cu(In,Ga,Al)(S,Se)₂), copper zinc tin sulfide (CZTS) and other CIS-based systems. In such embodiments, the transparent window layer is disposed on a support, wherein the support includes the transparent conductive layer.

Typically, the efficiency of a solar cell is defined as the electrical power that maybe extracted from a module divided by the power density of the solar energy incident on the cell surface. Using FIG. 2 as a reference, the incident light 120 passes through the support 110, transparent conductive layer 112, and the transparent window layer 114 before it is absorbed in the first semiconducting layer 116, where the conversion of the light energy to electrical energy takes place via the creation of electron-hole pairs.

In one embodiment of the present invention the photovoltaic device has a fill factor of greater than about 0.7. In another embodiment, the photovoltaic device has a fill factor in a range from about 0.65 to about 0.85. Fill factor (FF) equals the ratio between the maximum power that can be extracted in operation and the maximum possible for the cell under evaluation based on its J_{SC} and V_{OC}. Short-circuit current density (J_{SC}) is the current density at zero applied voltage. Open circuit voltage (V_{OC}) is the potential between the anode and cathode with no current flowing. At V_{OC} all the electrons and holes recombine within the device. This sets an upper limit for the work that can be extracted from a single electron-hole pair. In yet another embodiment, the photovoltaic device has an open circuit voltage (V_{OC}) of greater than about 810 mllliVolts.

Yet another aspect of the present invention provides a method to make a photovoltaic device. The method includes disposing a transparent conductive layer on a support; disposing a transparent window layer on the transparent conductive layer; and disposing a first semiconducting layer on the transparent window layer. The method of disposing the transparent window layer includes providing a target comprising a semiconducting material comprising cadmium and sulfur within an oxygen free environment; applying a plurality of direct current pulses to the target to create a pulsed direct current plasma; sputtering the target with the pulsed direct current plasma to eject a material comprising cadmium and sulfur into the plasma; and depositing a film comprising the ejected material onto the transparent conductive oxide layer.

### EXAMPLES

### Method 1: Preparation of a Film Comprising Cadmium Sulfide

### Example 1

A film comprising cadmium sulfide was prepared using a cadmium sulfide target. The cadmium sulfide target was subjected to a bipolar asymmetric DC pulse in a sputtering chamber at frequency of 100 kHz, reverse time (or pulse width) of 3.5 μs, and average power density of 1 W/cm². The sputtering chamber was maintained in an environment of argon. During the sputtering process, the pressure of the sputtering chamber was maintained at 1.33 Pascals (10 milliTorr). The film comprising cadmium sulfide was deposited on a support (for example, glass) maintained at a temperature of about 200 degrees Celsius to about 250 degrees Celsius.

### Comparative Example 1

A cadmium sulfide film was prepared using RF sputtering technique using the same average power and argon pressure with the same CdS target in the same vacuum chamber as described in Example 1, and deposited on a glass substrate maintained at a temperature of about 250 degrees Celsius.

TABLE 1

| | | | Carrier | Hall |
|---|---|---|---|---|
| | | Resistivity | Density | Mobility |
| | Annealing | (Ohm · cm) | (cm⁻³) | (cm²/V-s) |
| Comparative Example 1 | No | 2.1 × 10⁴ | 2.4 × 10¹³ | 12 |
| Example 1 | No | 1.1 × 10² | 7.6 × 10¹⁵ | 7.3 |

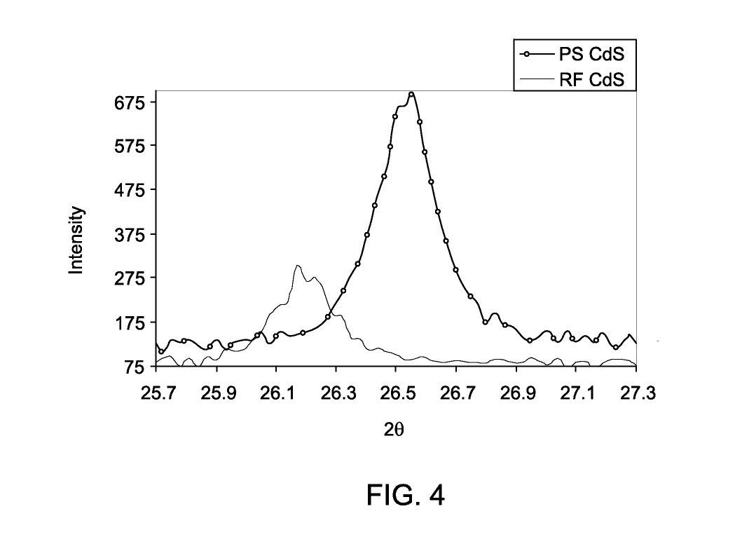

As can be seen from the X-ray diffraction data shown in FIG. 4, the cadmium sulfide of Example 1 showed better crystallinity when compared to the cadmium sulfide film of Comparative Example 1 prepared using RF sputtering method. It was observed using secondary electron microscope (SEM) that the film of Example 1 (using pulsed sputtering method) showed faceted grains with the size of about 60-80 nm, while the Comparative Example 1 film (using RF sputtering method) with the same thickness showed a microstructure including grains and cauliflower-like clusters in the size of about 20-40 nm. Further, it may be noted that the cadmium sulfide film of Example 1 displayed better electrical properties than the cadmium sulfide film of Comparative Example 1 (see Table 1). As shown in Table 1 the electrical properties of the cadmium sulfide films of Example 1, and Comparative Example 1 were characterized in ambient light. The Hall mobility and the carrier density of the films were measured using Hall measurement with the van der Pauw technique. It may be noted that the cadmium sulfide film of Example 1 displayed resistivity less than two orders of magnitude in comparison to the film of Comparative Example 1, thereby indicating that higher conductivity of the film of Example 1. Further, it may be noted that while the Hall mobility of the films of Example 1 and Comparative Example 1 are of the same order, the carrier density of the pulsed sputtered cadmium sulfide film of Example 1 is two orders of magnitude higher in comparison with the film of Comparative Example 1.

Further, it was observed that the films deposited on the support maintained at a temperature of about 200 degrees Celsius to 250 degrees Celsius displayed an increase in the transmission (integrated area between 400 nm to 600 nm) by about 6.5 percent compared to the deposition of a CdS film on a support maintained at a temperature 250 degrees Celsius employing the RF sputtering technique.

### Method 2: Preparation of the Cadmium Telluride Photovoltaic Device Having a Transparent Window Layer Comprising Cadmium Sulfide

A cadmium telluride photovoltaic device was made by depositing about 3 micrometers of cadmium telluride layer over a cadmium sulfide coated SnO₂:F transparent conductive oxide (TCO) glass using a close spaced sublimation process at a temperature of about 500 degrees Celsius. The TCO glass was 3 millimeters thick soda-lime glass, and coated with a SnO₂:F transparent conductive layer and a thin high resistance transparent ZnSnOₓ layer. The cadmium telluride layer over a cadmium sulfide coated SnO₂:F TCO glass was treated with cadmium chloride at a temperature of 400 degrees Celsius for about 20 minutes in air. At the end of the stipulated time, the coated SnO₂:F TCO glass was treated with a copper solution and subjected to annealing at a temperature of 200 degrees Celsius for a duration of 18 minutes. Gold was then deposited on the copper treated layer as the back contact by evaporation process.

Devices were prepared employing different materials as the transparent window layer. For example, in Comparative Example 2 cadmium sulfide deposited at a temperature of about 250 degrees Celsius using RF sputtering was employed as the transparent window layer, the same CdS deposition process as described in Comparative Example 1. In Comparative Example 3, cadmium sulfide deposited using a chemical bath deposition method (CBD) was employed as the transparent window layer. In Example 2, pulsed-sputtered cadmium sulfide deposited at a temperature of about 200 degrees Celsius to about 250 degrees Celsius was employed as the transparent window layer, the same CdS deposition process as described in Example 1. The thickness of the transparent window layer in all the three examples was maintained at about 80 nanometers. For statistical comparison of pulsed-sputtered CdS versus RF-sputtered CdS, 16 devices in Example 2 and 16 devices in Comparative Example 2 were produced and the average and standard deviation values are shown in Table 2.

TABLE 2

| | Type of | | | | |
|---|---|---|---|---|---|
| | Transparent | Efficiency | Voc | Jsc | |
| Example | Window Layer | (%) | (mV) | (mA/m²) | FF (%) |
| Comparative | RF sputtered | 12.45 ± | 807 ± 9 | 22.4 ± | 68.74 ± |
| Example 2 | cadmium sulfide | 0.84 | | 0.2 | 3.98 |
| Comparative | CBD Cadmium | 12.55 | 819 | 20.69 | 74.1 |
| Example 3 | sulfide | | | | |
| Example 2 | Pulsed sputtered | 13.31 ± | 827 ± 3 | 21.5 ± | 75.03 ± |
| | cadmium sulfide | 0.50 | | 0.7 | 1.11 |

It may be noted from Table 2 that the devices with the transparent window layer deposited using pulsed-sputtering displayed an increase in the FF and Voc when compared with the performance parameters of devices which had the transparent window layer prepared using CBD or RF-sputtering. The device in Example 2 displayed higher Voc and fill factor, thus giving higher efficiency. This may be attributed to an increase in the junction quality between the transparent window layer and the first semiconducting layer, using pulsed sputtered CdS films.

This written description uses examples to disclose some embodiments of the invention, including the best mode, and also to enable any person skilled in the art to practice the invention, including making and using any devices or systems, and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method, comprising:
providing a target comprising a semiconducting sulfide within an oxygen free environment;
applying a plurality of direct current pulses to the target to create a pulsed direct current plasma;
sputtering the target with the pulsed direct current plasma to eject a material comprising sulfur into the plasma; and
depositing a film comprising the ejected material onto a support.

2. The method of claim 1, wherein the semiconducting sulfide comprises cadmium, zinc, or combinations thereof.

3. The method of claim 1, wherein the sputtering of the target with the pulsed direct current plasma is carried out at a temperature in a range from about 50 degrees Celsius to about 550 degrees Celsius.

4. The method of claim 1, wherein the sputtering of the target with the pulsed direct current plasma is carried out at ambient temperature.

5. The method of claim 1, wherein the direct current pulses have a power density in a range of about 0.2 W/cm² to about 20 W/cm².

6. The method of claim 1, wherein the direct current pulses have a current density in a range of about 0.001 A/cm² to about 0.01 A/cm².

7. The method of claim 1, wherein the direct current pulses have a pulse width in a range of about 0.2 microseconds to about 50 microseconds.

8. The method of claim 1, wherein the direct current pulses are in a frequency range from about 10 kHz to about 400 kHz.

9. The method of claim 1, wherein the sputtering the target with the pulsed direct current plasma is carried out in an environment comprising argon.

10. The method of claim 1, wherein the film comprises a semiconducting sulfide having a formula (I):
ZnₓCd₁₋ₓS (I)
wherein “x” is in a range from 0 to about 1.

11. The method of claim 1, wherein the film comprises cadmium sulfide.

12. The method of claim 1, wherein the film has a thickness in a range from about 20 nanometers to about 200 nanometers.

13. The method of claim 1, wherein the film has an electrical resistivity in a range from about 0.1 Ohm-centimeter to about 1000 Ohm-centimeter.

14. The method of in claim 1, wherein the film comprises a microcrystalline morphology.

15. The method as defined in claim 1, further comprising the step of annealing the film.

16. A method of making a photovoltaic device, comprising:
disposing a transparent window layer on a support; and
disposing a first semiconducting layer on the transparent window layer;
wherein disposing the transparent window layer comprises:
providing a target comprising a semiconducting sulfide within an oxygen free environment;
applying a plurality of direct current pulses to the target to create a pulsed direct current plasma;
sputtering the target with the pulsed direct current plasma to eject a material comprising sulfur into the plasma; and
depositing a film comprising the ejected material onto the support.

17. The method of claim 16, wherein the first semiconducting layer comprises cadmium telluride.

18. The method of claim 16, wherein the transparent window layer comprises zinc sulfide, cadmium sulfide, or combinations thereof.

19. The method of claim 16, further comprising interposing a transparent conductive layer between the support and the transparent window layer.

20. The method of claim 16, wherein the semiconducting layer comprises a telluride, a selenide, a sulfide or combinations thereof.

21. The method of claim 16, wherein the transparent window layer further comprises zinc telluride, zinc selenide, cadmium selenide, cadmium sulfur oxide, copper oxide, or combinations thereof.

22. The method of claim 16, wherein the transparent window layer has a thickness in a range from about 5 nanometers to about 250 nanometers.

23. The method of claim 19, further comprising interposing a buffer layer disposed between the transparent conductive layer and the transparent window layer.

24. The device of claim 19, wherein the transparent conductive layer comprises a transparent conductive oxide selected from a group consisting of cadmium tin oxide, zinc tin oxide, indium tin oxide, aluminum-doped zinc oxide, zinc oxide, fluorine-doped tin oxide, and combinations thereof.

25. A method of making a photovoltaic device, comprising:
disposing a back contact layer on a support;
disposing a first semiconducting layer on the back contact layer; and
disposing a transparent window layer on the first semiconducting layer;
wherein disposing the transparent window layer comprises:
providing a target comprising a semiconducting material comprising cadmium and sulfur within an oxygen free environment;
applying a plurality of direct current pulses to the target to create a pulsed direct current plasma;
sputtering the target with the pulsed direct current plasma to eject a material comprising cadmium and sulfur into the plasma; and
depositing a film comprising the ejected material onto the first semiconducting layer.
